(19) United States
(12) Patent Application Publication
(10) Pub. No.: US 2025/0202497 A1
(43) Pub. Date: Jun. 19, 2025

(54) BIAS CIRCUIT FOR A DIGITAL-TO-ANALOGUE CONVERTER

(71) Applicant: COMMISSARIAT A L’ENERGIE ATOMIQUE ET AUX ENERGIES ALTERNATIVES, PARIS (FR)

(72) Inventor: Bertrand DUPONT, GRENOBLE (FR)

(21) Appl. No.: 18/980,981

(22) Filed: Dec. 13, 2024

(30) Foreign Application Priority Data
Dec. 15, 2023 (FR) 2314251

(51) Int. Cl. H03M 1/76; G02F 1/29

(52) U.S. Cl. CPC H03M 1/76; G02F 1/292

(57) ABSTRACT

An electronic circuit includes an output node adapted to supply an output current through a load circuit; a plurality of elementary source branches connected in parallel; a bias circuit comprising: a current mirror formed by a first bias branch carrying a reference current and a second bias branch; the second bias branch comprises: a follower transistor, a first bias cascode transistor and a second bias current mirror transistor; a first amplifier circuit configured to copy the electrical potential of the output node onto the drain of the first bias cascode transistor; a second amplifier circuit configured to generate a voltage on the gate of the first bias cascode transistor in order to regulate the voltage of its source to a predefined setpoint voltage.

### CROSS-REFERENCE TO RELATED APPLICATION

This application claims priority to foreign French patent application No. FR 2314251, filed on Dec. 15, 2023, the disclosure of which is incorporated by reference in its entirety.

### FIELD OF THE INVENTION

The invention relates to the field of circuits for converting a digital signal into an analogue signal, more particularly to the design of a current analogue-to-digital converter having a high linearity constraint.

### BACKGROUND

A digital-to-analogue converter is an electronic device that transforms digital signals into analogue signals. It is used when digital data need to be converted into an analogue form, for example in order to be used in audio systems or to control analogue equipment. The digital-to-analogue converter works by converting the digital data, generally expressed in binary form, into a corresponding analogue voltage and/or current.

Digital-to-analogue converters are used in numerous applications such as audio systems, industrial control systems, wireless communications and measuring instruments. They are essential to allowing interaction between digital and analogue systems by converting the digital data into analogue signals that can be understood by the analogue equipment.

More particularly, a current digital-to-analogue converter circuit is an electronic device that transforms digital signals into proportional analogue currents. Unlike a voltage digital-to-analogue converter, which generates an analogue voltage at the output, a current digital-to-analogue converter produces an analogue current at the output. Ideally, the output current is directly proportional to the digital input value. This current can then be converted into a voltage across a load resistor.

The conversion process in a current digital-to-analogue converter circuit involves the use of an array comprising a plurality of elementary current source branches. Each digital input value selects a (or multiple) source branch constituting a specific path for the current by activating or deactivating corresponding switches. This generates various output currents proportional to the digital input values.

The design of a current digital-to-analogue converter is mainly limited by the matching of the transistors, the dependency of the current on the supply voltage or on the earth, and also by the output impedance of the elementary current source branches that make up the converter. As far as the matching and the dependency of the power supplies are concerned, these can be adjusted by using appropriate dimensions for the transistors in the elementary current sources.

However, for an N-bit current digital-to-analogue converter, it is necessary to have 2^{N}−1 elementary current source branches. The output impedance of the current digital-to-analogue converter depends on the number of activated current sources. For a code ramp extending from 0 to 2^{N}−1, the variation in the output impedance of the converter brings about a systematic integrated nonlinearity error.

In order to understand the problem of linearity in current digital-to-analogue converters, FIG. 1 shows the following curves:
The first curve C1 shows the theoretical variation in the output current Is of the converter according to the number of activated elementary sources. The current Is moves between zero and an ideal maximum current value;
The second curve C2 shows the nonlinear real variation in the output current Iₛ of the converter according to the number of activated elementary sources. The current Is moves between zero and a real maximum current value;
The third curve C3 shows a theoretical linear modelling of the output current Iₛ of the converter according to the number of activated elementary sources. The current Is moves between zero and said real maximum current value.

For a digital-to-analogue converter, the measured real maximum current value Iₘₐₓ₋ᵣₑₑₗ is less than the theoretically calculated ideal maximum current value Imax-ideal. The nonlinearity is maximum for a midrange number of activated elementary sources, between the minimum number and the maximum number of activated elementary sources. INL (Integrated Non Linearity) is a measurement that assesses the linearity of a digital-to-analogue converter. It is a measurement of the greatest difference observed between the second curve C2 and the third curve C3 corresponding to perfectly linear operation between zero and the real maximum current value Imax-reel. More specifically, INL quantifies the differences between the real analogue current values produced by the converter and the ideal values of the third curve C3 that are expected over the entire conversion range. INL is generally expressed in LSB (Least Significant Bit). An INL of 0 LSB means that the DAC produces perfectly linear voltage values without any error.

Against this background, several problems have been clearly identified with current digital-to-analogue converters known from the prior art; more specifically, problems relating to errors due to the nonlinearity of the behaviour of the analogue-to-digital converter for a large number of activated elementary source branches.

Moreover, when designing a digital-to-analogue converter circuit, the output impedance needs to be higher than a critical threshold that depends on the specified INL, on the load resistance and on the number of bits of the digital-to-analogue converter. Typically, for a specified INL of the order of ½ LSB (Least Significant Bit), the target value of the output impedance becomes difficult to achieve for digital-to-analogue converters beyond 8-10 bits.

More generally, the invention can be used for converters having a linearity constraint by reducing the difference between theoretical behaviour and real behaviour.

We will start by introducing solutions known to those skilled in the art for improving the linearity of an analogue-to-digital converter having a plurality of elementary current source branches.

The first solution according to the prior art consists in stacking a plurality of cascoded transistors in each branch. The cascoded transistors are dimensioned so as to increase the output impedance of the converter circuit and thus reduce the amplitude of the nonlinearity. The disadvantage of this solution is not only a considerable increase in the surface area occupied by the circuit but also a reduction in the range of variation of the output voltage across the terminals of the load resistor at the output of the converter.

The second solution according to the prior art consists in adding a digital correction module in order to correct conversion errors due to the nonlinearity of the behaviour of the current digital-to-analogue converter. The digital correction circuit can use techniques such as gamma correction, linearity correction and interpolation correction to adjust the values of the analogue signals produced by the converter. The disadvantage of this solution is that it requires the introduction of additional complexity to the system, which results in a considerable increase in the surface area taken up by the circuit and to an increase in its power consumption. More specifically, the solution according to the prior art is based on the construction of a lookup table, which consists in matching the digital code received at the input to a modified code that allows steps to be taken to ensure that the measured curve approximates the ideal curve as far as possible. This requires the implementation of a large memory in order to store this table. This results in a considerable increase in the surface area taken up by the circuit.

### SUMMARY OF THE INVENTION

To compensate for the limitations of the existing solutions, the invention proposes an analogue-to-digital converter circuit in which the bias circuit comprises at least one amplifier circuit that increases the output impedance seen by the elementary current source branches. Several embodiments of the invention are put forward with implementation variants of the proposed solution.

The subject of the invention is an electronic circuit configured to convert an N-bit digital input signal into an output current, N being a non-zero natural number, said circuit comprising:
a supply node adapted to receive a supply voltage, and an electrical earth; an output node adapted to supply said output current through a target load circuit connected between firstly said output node and secondly a first reference node chosen from the electrical earth or the supply node;
a plurality of elementary source branches connected in parallel between the output node and a second reference node, which is separate from said first reference node and chosen from the electrical earth or the supply node; each elementary source branch comprising:
   a control transistor controlled by one bit and having a drain connected to the output node;
   an elementary cascode transistor and an elementary current recopying transistor, which are connected in series with the control transistor;
a bias circuit comprising:
   a current mirror formed by a first bias branch carrying a reference current and a second bias branch; the first bias branch comprises a first generator of said reference current and a first bias current mirror transistor receiving the reference current;
   the second bias branch comprises, in this order: a follower transistor, a first bias cascode transistor and a second bias current mirror transistor, which are connected in series; the gate of the second bias current mirror transistor and the gate of each elementary current recopying transistor being connected to the gate of the first bias current mirror transistor; the gate of each elementary cascode transistor being connected to the gate of the first bias cascode transistor;
   a first amplifier circuit configured to copy the electrical potential of the output node onto the drain of the first bias cascode transistor;
   a second amplifier circuit configured to generate a voltage on the gate of the first bias cascode transistor to regulate the voltage of the source of said first bias cascode transistor to a predefined setpoint voltage.

According to a particular aspect of the invention, the first amplifier circuit is an operational amplifier having a noninverting input connected to the output node, an inverting input connected to the drain of the first bias cascode transistor, and an output connected to the gate of the follower transistor.

According to a particular aspect of the invention, the second amplifier circuit is an operational amplifier having a noninverting input configured to receive a first bias voltage, an inverting input connected to the source of the first bias cascode transistor, and an output connected to the gate of the first bias cascode transistor and intended to generate said regulated voltage.

According to a particular aspect of the invention, the second amplifier circuit comprises a second current generator and a first amplification transistor, which is supplied with power by said dedicated second current generator and has: a gate connected to the source of the first bias cascode transistor; and a drain connected to the gate of the first bias cascode transistor.

According to a particular aspect of the invention, the first bias branch comprises a second bias cascode transistor connected between the first generator of the reference current and the first bias current mirror transistor.

According to a particular aspect of the invention, the bias circuit moreover comprises a third amplifier circuit having a noninverting input configured to receive a second bias voltage, an inverting input connected to the source of the second bias cascode transistor, and an output connected to the gate of the second bias cascode transistor.

According to a particular aspect of the invention, the second bias voltage corresponds to the first bias voltage.

According to a particular aspect of the invention, the bias circuit moreover comprises a second amplification transistor supplied with power by a dedicated third current generator and having a gate connected to the source of the second bias cascode transistor and having a drain connected to the gate of the second bias cascode transistor.

The subject of the invention is also a phase-configurable photonic device comprising:
a waveguide for guiding an input light beam generated by a laser source;
a transmitting or receiving antenna connected to the waveguide;
a resistive element intended to heat the waveguide by way of the Joule effect so as to manage the propagation index of the waveguide in order to configure the phase of the out-of-phase light beam;
an electronic circuit according to the invention, configured to inject a control current through the resistive element on the basis of a digital control signal in order to manage the heating of at least one section of the waveguide; the resistive element corresponding to said target load circuit.

The subject of the invention is also an optical phased array configured to direct a light beam in a predetermined direction, comprising: a plurality of phase-configurable photonic devices according to the invention, which are supplied with power by a common laser source; each phase-configurable photonic device being controlled by a dedicated digital control signal generated by control means.

### BRIEF DESCRIPTION OF DRAWINGS

Other features and advantages of the present invention will become more apparent upon reading the description that follows with reference to the appended drawings below.

FIG. 1 shows curves for the behaviour of a current digital-to-analogue converter according to the prior art. This figure has already been described in a previous section.

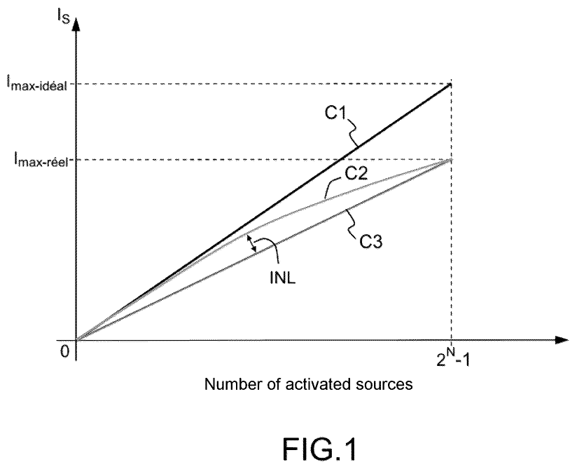

FIG. 2 shows a circuit diagram of the digital-to-analogue converter according to a first embodiment of the invention.

FIG. 3 shows a circuit diagram of the digital-to-analogue converter according to a second embodiment of the invention.

FIG. 4 shows a circuit diagram of the digital-to-analogue converter according to a third embodiment of the invention.

FIG. 5a shows a first photonic device implementing the converter circuit according to the invention.

FIG. 5b shows a second photonic device implementing the converter circuit according to the invention.

### DETAILED DESCRIPTION

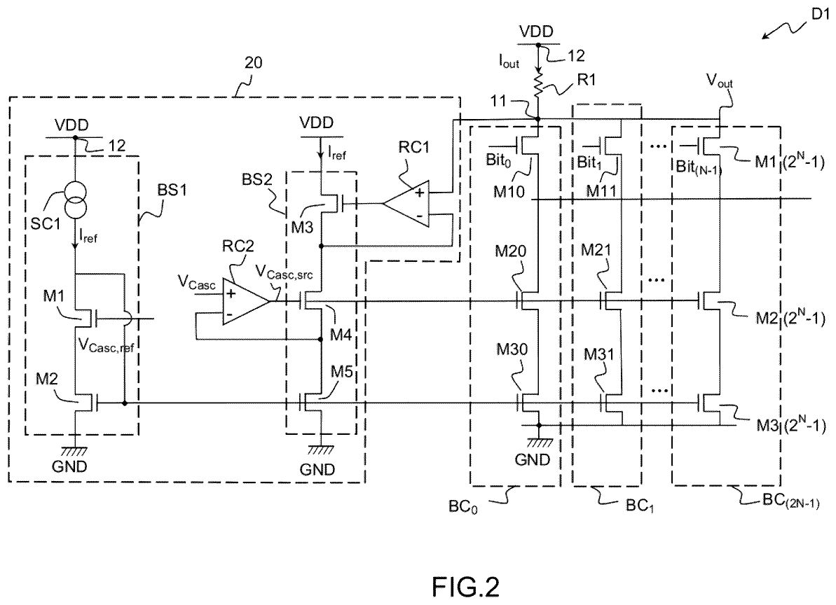

FIG. 2 shows a circuit diagram of the digital-to-analogue converter circuit D1 according to a first embodiment of the invention. The circuit D1 is configured to convert a digital input signal BW=[Bit₀ Bit₁ Bit₂ Bit₃ . . . Bit_{N-1}] having N bits of rank i=0 to N−1 into an output current Iₒᵤₜ, N being a non-zero natural number. The circuit D1 comprises an output node 11 adapted to supply an analogue output signal Vₒᵤₜ, a supply node 12 adapted to receive a supply voltage VDD, a plurality of elementary source branches BCⱼ of rank j=0 to 2^{N}−1 and a bias circuit 20.

A target load circuit is connected to the digital-to-analogue converter circuit D1. The target load circuit is intended to receive the output current Iₒᵤₜ. The target load current may be, as an enlightening, nonlimiting example, a resistive element or an inductive element or a capacitive element or an electronic circuit to be supplied with power by the output current Iₒᵤₜ. In the remainder of the description, the target load circuit is produced by a resistive element R1, but the invention remains compatible with any load circuit receiving the output current Iₒᵤₜ according to the application context of the invention. A target load circuit formed by at least one inductive element produces a power converter, for example. A target load circuit formed by at least one capacitive element produces a sampling circuit, for example. A target load circuit to be supplied with power by the output current Iₒᵤₜ is an amplifier or a logic circuit, for example.

In the example shown, the resistive element R1 is connected between the supply node 12 and the output node 11. The resistive element R1 is intended to carry the output current Iₒᵤₜ, the level of which depends on the digital input signal BW. The resistive element R1 is thus used to convert the output current Iₒᵤₜ into a voltage drop between the supply node 12 and the output node 11 and thus into an analogue output signal Vₒᵤₜ.

Alternatively, the resistive element R1 uses the output current Iₒᵤₜ to produce an amount of heat by way of the Joule effect. This is useful for applications that require local and modulable heating around the resistive element R1.

The digital-to-analogue converter circuit D1 comprises 2^{N}−1 elementary source branches BCⱼ connected in parallel between the output node 11 and the electrical earth GND. Each elementary source branch BCⱼ comprises a control transistor M1j, an elementary cascode transistor M2j and an elementary current recopying transistor M3j.

For each elementary source branch BCⱼ of rank j, the drain of the control transistor M1j is connected to the output node 11 common to all the source branches; the drain of the elementary cascode transistor M2j is connected to the source of the control transistor M1j; the drain of the elementary current recopying transistor M3j is connected to the source of the elementary cascode transistor M2j; the source of the elementary current recopying transistor M3j is connected to the electrical earth GND; the gate of the control transistor M1j is controlled by one bit of the digital input signal BW and the respective gates of the elementary cascode transistor M2j and the elementary current recopying transistor M3j are biased by the bias circuit 20. Thus, the output impedance r_{ds} of the two transistors M2j, M3j of the elementary source branch BCⱼ is partly determined by the bias circuit 20. The combination of the transistors M2j, M3j of the elementary source branch BCⱼ behaves like a current source having an output impedance r_{ds}. The control transistor M1j acts as a current switch in the elementary source branch BCⱼ. When the control transistor M1j is in the on state, a current path is set up from the supply node 12 to the electrical earth GND through the load impedance R1 and then the elementary source branch BCⱼ associated with said control transistor. Thus, each elementary source branch BCⱼ has an ability to generate an elementary current I_{src} through the load impedance R1. If the dimensioning of the transistors of the source branches is identical, the elementary currents are identical. In this case, ideally, when the bits of the digital input signal BW activate M source branches, the output current Iₒᵤₜ passing through the load impedance R1 is equal to M times the elementary current I_{src}. The transistors of each elementary source branch BCⱼ are dimensioned so as to work under saturation conditions for a predetermined maximum output current value Iₒᵤₜ, a predetermined supply voltage VDD and a predetermined value of the output impedance.

To take account of the significance of the bits in the digital input signal BW=[Bit₀ Bit₁ Bit₂ Bits Bit_{N-1}], the distribution of the bits with regard to the control transistors M1j is produced as follows: the bit of rank i=0 Bit₀ having the least significance (as an illustrative, nonlimiting example) controls the gate of the control transistor M10 of the elementary source branch BC₀; the bit of rank i=1 Bit₁ having the next significance controls the gates of the control transistors M11 and M12 of the next 2ⁱ⁼¹ source branches BC₁ and BC₂; the bit of rank i=2 Bit₂ having the next significance controls the gates of the control transistors M13 to M16 of the next 2ⁱ⁼² source branches BC₃ to BC₆ and so on as far as the bit Bit_{N-1} of rank N−1 that controls the gates of the control transistors of the last 2^{N-1} source branches BCⱼ. The sequential order of the distribution has been described to make it easier to understand the distribution of control, but it is not obligatory. In general terms, the bit of rank i=0 to N−1 controls the gates of the control transistors of 2ⁱ source branches BCⱼ chosen from the 2^{N-1} source branches of the converter circuit D1. Thus, when the bit of rank i Bitᵢ (and therefore of significance i) is in logic state “1”, the associated 2ⁱ source branches BC are on. This leads to the injection of a current associated with said bit Bitᵢ; the injected current is proportional to the significance of said bit Bitᵢ and is equal to 2ⁱ*I_{src}.

It is also conceivable to add a digital circuit (not shown) that is configured to convert the digital input signal BW in order to convert the most significant bits into thermometric codes for controlling the gates of the control transistors M1j, which reduces the disadvantages relating to the differential nonlinearity (DNL) of the converter.

The bias circuit 20 comprises a current mirror formed by a first bias branch BS1 carrying a reference current I_{ref} and a second bias branch BS2 coupled to the first bias branch BS1. The first bias branch BS1 comprises a first generator SC1 of said reference current I_{ref}, a first bias current mirror transistor M2.

The second bias branch BS2 comprises, in this order: a follower transistor M3, a first bias cascode transistor M4 and a second bias current mirror transistor M5, which are connected in series from the supply node 12 to the electrical earth GND.

The specific implementation shown for the current mirror formed by the bias branches BS1, BS2 is presented as a nonlimiting example. The invention remains compatible with all current mirror architectures in general terms.

Advantageously, and optionally, the first bias branch BS1 comprises a second bias cascode transistor M1. The second bias cascode transistor M1 improves the current mirroring from the first bias branch BS1 to the second bias branch BS2. In an implementation without a second bias cascode transistor M1, the first bias current mirror transistor M2 is connected as a diode directly connected to the first generator SC1.

More specifically, the first current generator SC1 is connected between the supply node 12 and the drain of the second bias cascode transistor M1. The drain of the first bias current mirror transistor M2 is connected to the source of the second bias cascode transistor M1. The source of the first bias current mirror transistor M2 is connected to the electrical earth GND. The gate of the bias current mirror transistor M2 is connected to the output of the first current generator SC1. In the first embodiment, the second bias cascode transistor M1 is biased by a reference voltage (also called a setpoint voltage) V_{casc,ref} originating from an external source (not shown).

The gate of the first bias current mirror transistor M2 is connected to the drain of the second bias cascode transistor M1 and to the gate of the second bias current mirror transistor M5. The cascoded connection of the second bias cascode transistor M1 imposes a drain voltage on the second bias current mirror transistor M2. The drain of the follower transistor M3 is connected to the supply node 12. The drain of the first bias cascode transistor M4 is connected to the source of the follower transistor M3. The drain of the second bias current mirror transistor M5 is connected to the source of the first bias cascode transistor M4. The source of the second bias current mirror transistor M5 is connected to the electrical earth GND. Connecting the gates of the first mirror transistor M2 and the second mirror transistor M5 and having a potential that is very close on the drains of M2 and M5 ensures that the reference current I_{ref} (or a multiple of I_{ref}) of the first bias branch BS1 is properly mirrored into the second bias branch BS2, in particular because this limits the Early effect.

For each elementary source branch BCⱼ, the gate of the elementary cascode transistor M2j is connected to the gate of the first bias cascode transistor M4 of the second bias branch BS2. This couples each elementary source branch BCⱼ to the second bias branch BS2. Moreover, for each elementary source branch BCⱼ, the gate of the elementary current recopying transistor M3j is connected to the gate of the first bias current mirror transistor M2 of the first bias branch BS1. This couples each elementary source branch BCⱼ to the first bias branch BS1. The dual coupling of each elementary source branch BCⱼ mirrors the reference current (or a multiple of the current) onto any one of the source branches BCⱼ when said source branch is in the on state.

The bias circuit 20 also comprises a first amplifier circuit RC1 configured to copy the output voltage Vₒᵤₜ onto the drain of the first bias cascode transistor M4. This achieves a behaviour of the second bias branch BS2 similar to that of the source branches BCⱼ, which see the variations in the output voltage Vₒᵤₜ during operation of the digital-to-analogue converter circuit D1. The improvement in the similarity of the voltage variations seen by the second bias branch BS2 and the source branches BCⱼ improves the linearity of the digital-to-analogue converter D1. By way of example, the amplifier circuit RC1 is an operational amplifier having a noninverting input connected to the output node 11, an inverting input connected to the drain of the first bias cascode transistor M4, and an output connected to the gate of the follower transistor M3.

The bias circuit 20 moreover comprises a second amplifier circuit RC2, which is configured to generate a regulated voltage V_{casc,src} on the gate of the first bias cascode transistor M4 from at least the voltage of the source of said first bias cascode transistor M4. The combination of the second amplifier circuit RC2 with the bias cascode transistor M4 forms a regulated cascode. Furthermore, the second amplifier circuit RC2 is connected so as to regulate the gate voltage of the first bias cascode transistor M4 and thus keep the drain of the second bias current mirror transistor M5 at a first predetermined bias voltage V_{casc}.

According to the first embodiment, the second amplifier circuit RC2 is produced by an operational amplifier having a noninverting input configured to receive a first bias voltage V_{casc}, an inverting input connected to the source of the first bias cascode transistor M4, and an output connected to the gate of the first bias cascode transistor M4 and intended to generate the regulated voltage V_{casc,src}. This connection of the second amplifier circuit RC2 increases the output impedance of the converter circuit D1 and thus improves the linearity of the output current lout on the basis of the number of activated source branches BCⱼ. The reason is that using the second amplifier RC2, with gain A, connected as a “regulated cascode”, multiplies the output impedance rₒᵤₜ by a factor of A+1 compared to a cascode connection according to the prior art, without the second amplifier RC2. Advantageously, the output power of the second amplifier circuit RC2 is greater than four times that of the first amplifier circuit RC1. This allows the second amplifier circuit RC2 to control the gates of the 2^{N}−1 load transistors M2j in addition to the gate of the first bias cascode transistor M4.

We have described a combination of technical elements that is formed by: firstly, the first amplifier RC1, which mirrors the output voltage Vₒᵤₜ into the second bias branch BS2; and, secondly, the second amplifier circuit RC2, which regulates the gate voltage of the first bias cascode transistor M4. This combination achieves improved linearity of the output current Iₒᵤₜ on the basis of the number of activated source branches BCⱼ (and therefore on the basis of the bits in logic state “1”). This improves the linearity of the output current while avoiding expanding or adding multiple cascode stages in the source branches BCⱼ. The solution according to the invention thus saves surface area taken up by the converter circuit compared with the solutions of the prior art without adversely affecting linearity.

Advantageously, and optionally, each elementary source branch BCⱼ is not limited to a single elementary cascode transistor M2j and thus comprises a plurality of elementary cascode transistors M2j, M2j′, M2j″ . . . . Advantageously, and optionally, the second bias branch BS2 is not limited to a single first bias cascode transistor M4 and thus comprises a plurality of bias cascode transistors M4, M4′, M4″ . . . . The biasing of at least one bias cascode transistor among said plurality of bias cascode transistors is regulated by at least one amplifier circuit RC2 connected as described above.

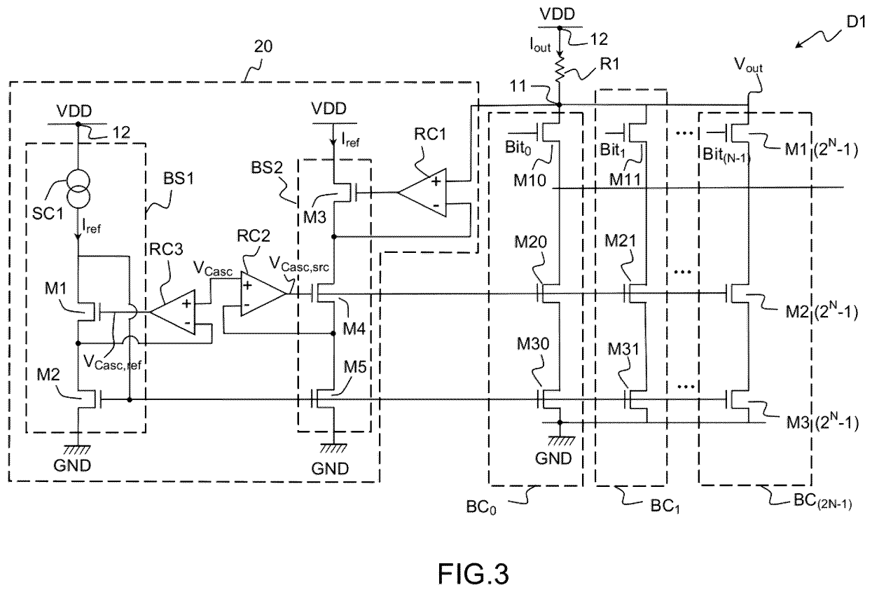

FIG. 3 shows a circuit diagram of the digital-to-analogue converter D1 according to a second embodiment of the invention. The structural and functional features described for the first embodiment remain valid for the second embodiment. In the embodiment shown, the bias circuit 20 moreover comprises a third amplifier circuit RC3 having a noninverting input configured to receive a second bias voltage V_{casc}, an inverting input connected to the source of the second bias cascode transistor M1, and an output connected to the gate of the second bias cascode transistor M1. The third amplifier circuit RC3 then controls the gate of the second bias cascode transistor M1 of the first bias branch BS1 and keeps the drain of the first bias current mirror transistor M2 at the second predetermined bias voltage V_{casc}. The combination of the third amplifier circuit RC3 with the second bias cascode transistor M1 forms a regulated cascode connection. This improves the symmetry and thus the current mirroring between the first bias branch BS1 and the second bias branch BS2. In the case shown, and optionally, the second bias voltage also corresponds to the first bias voltage V_{casc} of the second amplifier circuit RC2.

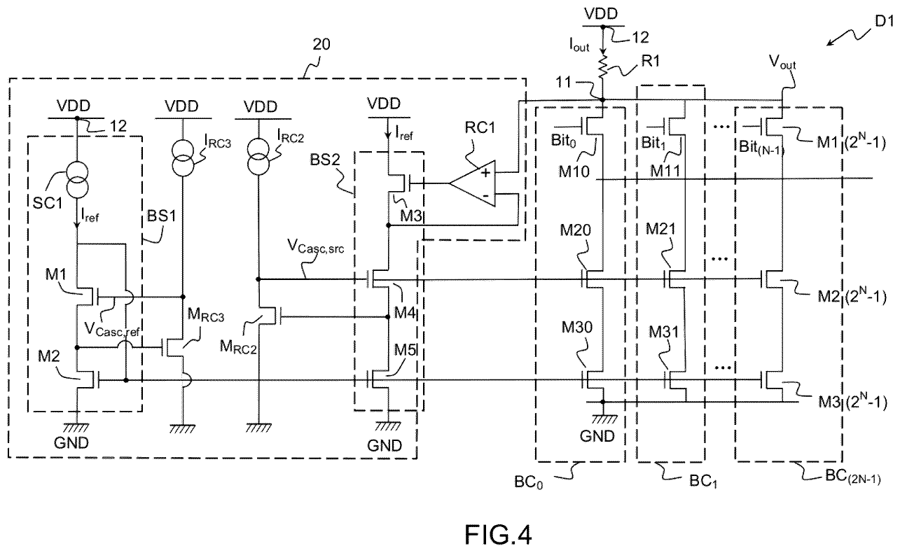

FIG. 4 shows a circuit diagram of the digital-to-analogue converter D1 according to a third embodiment of the invention. The structural and functional features described for the first and second embodiments remain valid for the third embodiment. The difference over the other embodiments lies in an alternative implementation of the second amplifier circuit and/or third amplifier circuit while retaining the same technical advantages relating to these two elements.

In this embodiment, the second amplifier circuit comprises a second current generator I_{RC2} and a first amplification transistor M_{RC2}, which is supplied with power by said dedicated second current generator I_{RC2}. The gate of the first amplification transistor M_{RC2} is connected to the drain of the second bias current mirror transistor M5 (and therefore to the source of said first bias cascode transistor M4). The drain of the first amplification transistor M_{RC2} is connected to the gate of the first bias cascode transistor M4. In this embodiment, the first bias voltage V_{casc} corresponds to the gate-source voltage VGS, M_{RC2} of the first amplification transistor M_{RC2}. The first amplification transistor M_{RC2} is connected as a common source amplifier. The choice of the intensity of the current I_{RC2} and the dimensioning in terms of width and length of the first amplification transistor M_{RC2} generate a regulated voltage V_{casc, src} on the gate of the first bias cascode transistor M4 from the voltage of the source of said first bias cascode transistor M4.

Similarly, in this embodiment, the third amplifier circuit comprises a third current generator I_{RC3} and a second amplification transistor M_{RC3}, which is supplied with power by said dedicated third current generator I_{RC3}. The gate of the second amplification transistor M_{RC2} is connected to the drain of the first bias current mirror transistor M2 (and therefore to the source of the second bias cascode transistor M1). The drain of the second amplification transistor M_{RC3} is connected to the gate of the second bias cascode transistor M1. In this embodiment, the second bias voltage V_{casc} corresponds to the gate-source voltage V_{GS,MRC3} of the second amplification transistor M_{RC3}. The second amplification transistor M_{RC3} is connected as a common source amplifier. The choice of the intensity of the current I_{RC3} and the dimensioning in terms of width and length of the second amplification transistor M_{RC3} generate a regulated voltage V_{casc,ref} on the gate of the second bias cascode transistor M1 from the voltage of the source of said second bias cascode transistor M1.

We emphasize that the implementation choices for producing the second and third amplifier circuits are independent. It is possible to opt for: firstly a differential operational amplifier to produce the second amplifier circuit and secondly connection of an amplification transistor as a common source to produce the third amplifier circuit, or vice versa.

In general terms for all embodiments of the invention, the combination of the first amplifier circuit RC1 and the second amplifier circuit RC2 (or M_{RC2}) has a synergy that regulates the bias of the drain and the source of the first bias cascode transistor M4 at the same time and thus regulates the bias of the gate of said first bias cascode transistor M4. Regulating the bias of said gate reduces the difference between the real behaviour and the theoretical behaviour of the converter circuit of the digital-to-analogue converter D1.

The invention has been explained using NMOS transistors as a nonlimiting illustrative example. Nothing prevents the same solution from being implemented using PMOS transistors. Alternatively, a person skilled in the art can adapt the proposed architecture described in FIGS. 2 to 4 with an implementation based on PMOS transistors and/or a complementary mixed NMOS/PMOS implementation. In the case of an implementation using exclusively PMOS, the target load circuit is connected between the output node 11 and the electrical earth GND; the elementary source branches BCⱼ are connected in parallel between the output node 11 and the supply node 12.

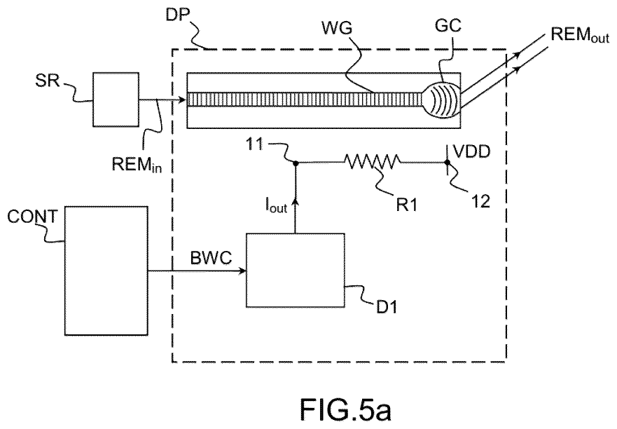

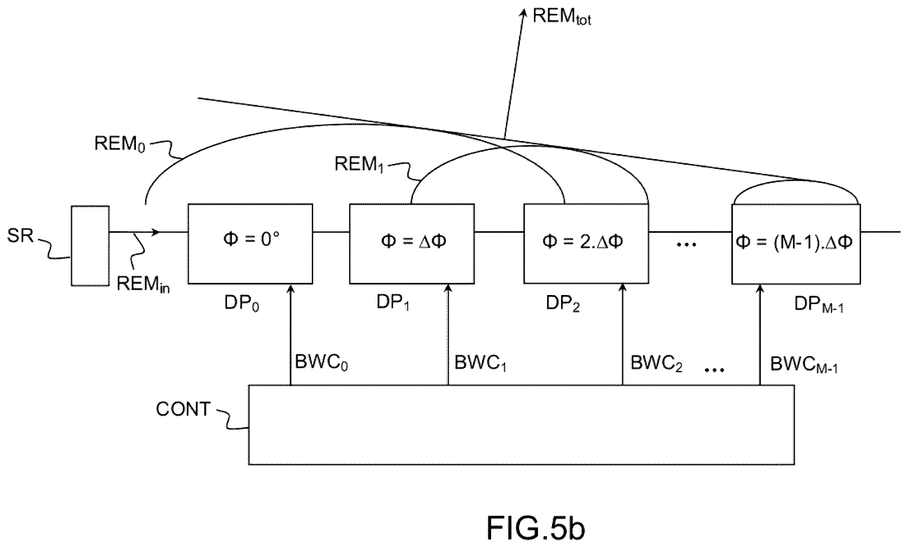

FIG. 5a shows a first photonic device DP implementing the converter circuit according to the invention.

The invention can be used in the context of a first phase-configurable photonic device DP. The photonic device DP comprises a waveguide WG, a transmitting antenna GC, a resistive element R1 and an electronic digital-to-analogue converter circuit D1 according to any one of the embodiments of the invention.

The waveguide WG is configured to guide an input light beam REMᵢₙ generated by a laser source SR. The waveguide WG is a microstructure integrated on a substrate made from a semiconductor material. The laser source may be external or integrated on the same semiconductor substrate.

The transmitting antenna GC is connected to the output of the waveguide WG and configured to transmit an out-of-phase light beam REMₒᵤₜ. The transmitting antenna GC is produced by a grating coupler integrated on the semiconductor substrate.

The resistive element R1 corresponds to the target load circuit connected to the output node 11 of the electronic digital-to-analogue converter circuit D1. The resistive element R1 is intended to heat the waveguide WG by way of the Joule effect so as to manage the propagation index of the waveguide WG in order to configure the phase of the out-of-phase light beam REMₒᵤₜ.

Local modification of the propagation index modifies the phase of the fraction of the signal transmitted by laser source SR that passes through the waveguide WG and that continues as far as the transmitting antenna GC. The resistance of the resistive element R1 is between 10Ω and 100 kΩ. The digital-to-analogue converter circuit D1 is configured to control the intensity of the current carried by the resistive element R1 on the basis of a digital control signal BWC. The digital control signal BWC is generated by a control unit CONT. The digital control signal BWC is coded according to the desired heating, which depends on the targeted phase shift.

FIG. 5b shows a second photonic device OPA implementing the converter circuit according to the invention. The second photonic device OPA is an optical phased array. The invention is particularly advantageous in the context of a photonic device of optical phased array type. An optical phased array is a photonic device that directs a light beam in a predetermined direction without using mechanical parts.

The second photonic device OPA comprises a plurality of phase-configurable photonic devices DPₘ of rank m=0 to M−1. The phase-configurable photonic devices DPₘ form a photonic array. Each phase-configurable photonic device DPₘ receives a dedicated digital control signal BWCₘ from the control unit CONT. All of the waveguides WG of the photonic devices DPₘ are supplied with power by a common laser source SR. The common laser source SR generates an input light beam REMᵢₙ that is divided into M fractions. Each fraction is guided by the waveguide WG of an associated photonic device DPₘ. Ideally, the phase-configurable photonic devices DPₘ are configured so as to create a constant phase shift (modulo 2.pi) for each phase-configurable photonic device DPₘ of rank m in relation to the next phase-configurable photonic device DPₘ₊₁ of rank m+1. The output light beam is obtained by superimposing the various out-of-phase light beams REM₀, REM₁ to REM_{M-1}.

As a nonlimiting example, the photonic device D2 comprises an array of 256 phase-configurable photonic devices DPₘ and thus 256 digital-to-analogue converter circuits D1 in a 5×5 mm² CMOS circuit. In this context, the solution according to the invention has a particular advantage associated with a reduced surface area of the 256 digital-to-analogue converter circuits D1 combined with improved linearity. The improved linearity introduces a more precise phase shift between the various antennas of the OPA.

The implementation of the converter circuit according to the invention has been described for a transmitting photonic device as a nonlimiting example. The invention also remains compatible, and has the same advantages, for a photonic device in which the antenna GC is configured to receive. In this case, the antennas GC receive a stream from the scene and it is possible to favour one receiving direction by modulating the phases of the antennas.

1. An electronic circuit (D1) configured to convert an N-bit digital input signal (BW) into an output current (Iₒᵤₜ), N being a non-zero natural number, said circuit (D1) comprising:
a supply node adapted to receive a supply voltage (VDD), and an electrical earth (GND);
an output node adapted to supply said output current (Iₒᵤₜ) through a target load circuit (R1) connected between firstly said output node and secondly a first reference node chosen from the electrical earth (GND) or the supply node;
a plurality of elementary source branches (BC₀, BC₁, BC_{K}) connected in parallel between the output node and a second reference node, which is separate from said first reference node and chosen from the electrical earth (GND) or the supply node; each elementary source branch (BCᵢ) comprising:
a control transistor (M10, M11) controlled by one bit and having a drain connected to the output node;
an elementary cascode transistor (M20, M21) and an elementary current recopying transistor (M30, M31), which are connected in series with the control transistor (M10, M11);
a bias circuit comprising:
a current mirror formed by a first bias branch (BS1) carrying a reference current (I_{ref}) and a second bias branch (BS2); the first bias branch (BS1) comprises a first generator (SC1) of said reference current (I_{ref}) and a first bias current mirror transistor (M2) receiving the reference current (I_{ref});
the second bias branch (BS2) comprises, in this order: a follower transistor (M3), a first bias cascode transistor (M4) and a second bias current mirror transistor (M5), which are connected in series; the gate of the second bias current mirror transistor (M5) and the gate of each elementary current recopying transistor (M30, M31) being connected to the gate of the first bias current mirror transistor (M2); the gate of each elementary cascode transistor (M20, M21) being connected to the gate of the first bias cascode transistor (M4);
a first amplifier circuit (RC1) configured to copy the electrical potential of the output node (Vₒᵤₜ) onto the drain of the first bias cascode transistor (M4);
a second amplifier circuit (RC2, M_{RC2}) configured to generate a voltage (V_{casc,src}) on the gate of the first bias cascode transistor (M4) to regulate the voltage of the source of said first bias cascode transistor (M4) to a predefined setpoint voltage (V_{casc}).

2. The electronic circuit (D1) according to claim 1, wherein the first amplifier circuit (RC1) is an operational amplifier having a noninverting input connected to the output node, an inverting input connected to the drain of the first bias cascode transistor (M4), and an output connected to the gate of the follower transistor (M3).

3. The electronic circuit (D1) according to claim 1, wherein the second amplifier circuit (RC2) is an operational amplifier having a noninverting input configured to receive a first bias voltage (V_{casc}), an inverting input connected to the source of the first bias cascode transistor (M4), and an output connected to the gate of the first bias cascode transistor (M4) and intended to generate said regulated voltage (V_{casc,src}).

4. The electronic circuit (D1) according to claim 1, wherein the second amplifier circuit (RC2) comprises a second current generator (I_{RC2}) and a first amplification transistor (M_{RC2}), which is supplied with power by said dedicated second current generator (I_{RC2}) and has:
a gate connected to the source of the first bias cascode transistor (M4);
and a drain connected to the gate of the first bias cascode transistor (M4).

5. The electronic circuit (D1) according to claim 1, wherein the first bias branch (BS1) comprises a second bias cascode transistor (M1) connected between the first generator (SC1) of the reference current (I_{ref}) and the first bias current mirror transistor (M2).

6. The electronic circuit (D1) according to claim 5, wherein the bias circuit moreover comprises a third amplifier circuit (RC3) having a noninverting input configured to receive a second bias voltage (V_{casc}), an inverting input connected to the source of the second bias cascode transistor (M1), and an output connected to the gate of the second bias cascode transistor (M1).

7. The electronic circuit (D1) according to claim 6, wherein the second amplifier circuit (RC2) is an operational amplifier having a noninverting input configured to receive a first bias voltage (Vcasc), an inverting input connected to the source of the first bias cascode transistor (M4), and an output connected to the gate of the first bias cascode transistor (M4) and intended to generate said regulated voltage (Vcasc,src), and
wherein the second bias voltage (V_{casc}) corresponds to the first bias voltage (V_{casc}).

8. The electronic circuit (D1) according to claim 5, wherein the bias circuit moreover comprises a second amplification transistor (M_{RC3}) supplied with power by a dedicated third current generator (I_{RC3}) and having a gate connected to the source of the second bias cascode transistor (M1) and having a drain connected to the gate of the second bias cascode transistor (M1).

9. A phase-configurable photonic device (DP) comprising:
a waveguide (WG) for guiding an input light beam (REMᵢₙ) generated by a laser source (SR);
a transmitting or receiving antenna (GC) connected to the waveguide (WG);
a resistive element (R1) intended to heat the waveguide (WG) by way of the Joule effect so as to manage the propagation index of the waveguide (WG) in order to configure the phase of the out-of-phase light beam (REM);
an electronic circuit (D1) according to claim 1, configured to inject a control current (Iₒᵤₜ) through the resistive element (R1) on the basis of a digital control signal (BWC) in order to manage the heating of at least one section of the waveguide (WG); the resistive element (R1) corresponding to said target load circuit.

10. An optical phased array (OPA) configured to direct a light beam (REMₜₒₜ) in a predetermined direction, comprising:
a plurality of phase-configurable photonic devices (DP₁, DP₂, DP₃) according to claim 9, which are supplied with power by a common laser source (SR); each phase-configurable photonic device (DP₀, DP₁, DP₂, DP₃) being controlled by a dedicated digital control signal (BWC₀, BWC₁, BWC₂,BWC₃) generated by control means (CONT).
